(19) United States
(12) Patent Application Publication
(10) Pub. No.: US 2008/0131798 A1
(43) Pub. Date: Jun. 5, 2008

(54) Biologically photoconductive organic dispersion

(76) Inventors: Reginald Parker, Tallahassee, FL (US); Jesse Edwards, Tallahassee, FL (US)

Correspondence Address: Jerome J. Norris;Norris, Braden, Melton & Gregersen, PLLC, Suite 305, 1901 Pennsylvania Avenue, N.W., Washington, DC, 20006, US

(21) Appl. No.: 11/607,018

(22) Filed: Dec. 1, 2006

(51) Int. Cl. H01L 31/00

(52) U.S. Cl. 430/56

(57) ABSTRACT

A biologically photoconductive dispersion comprising:
a donor/acceptor blend of a single layer, wherein the donor domains is a synthetic polymer, and the acceptor domains is
a liquid organic semiconductor composite comprising, by weight about 14% single walled carbon nanotubes (SWNTs), about 57% of a biopolymer selected from lignin or melanin, and a dopant selected from the group consisting of iodine, phosphorous or boron.

### BACKGROUND OF THE INVENTION

I. Field of the Invention

The present invention relates to improved biologically photoconductive dispersions characterized by increased photovoltaic capability, increased electric conductivity, and increased print capability.

II. Description of the Related Art

In photovoltaic, optoelectronic, semiconductor and other electronic devices, inorganic materials such as silicon and gallium arsenide are the dominant organic materials utilized. Nevertheless, in the 1970s the discovery of electrical conductivity in organic polymers created alternatives to these inorganic materials.

For example, organic materials are characterized by significant advantages over inorganic materials in that they are more robust, have greater mechanical flexibility, are easier to process, cheaper in cost, and they have better biocompatibility than the harder inorganic materials.

With regard to conducting organic materials, U.S. Pat. No. 4,488,943 discloses methods of manufacturing polymer blends and their use in photochemical cells for conversion of solar energy to electricity.

Photovoltaic devices containing organic material layers and having high conversion efficiency is disclosed in U.S. Pat. No. 5,201,961.

There is also the use of synthetic polyindoles used in a variety of devices. In this connection, U.S. Pat. No. 5,290,891 disclose a process for preparing polymers based on polyindoles by polymerization of indole in the presence of an oxidizing agent and a solvent.

One disadvantage of using synthetic materials in photovoltaic applications is its limited photon absorption capability due to the fact that the efficiency of the device is directly related to the number of photons absorbed, and for that reason, synthetic polyindols are less than ideal for these applications.

Another class of materials that are distinct from synthetic polymers are biopolymers that are found naturally occurring throughout the biosphere. Biopolymers are significant in that they offer an advantage over organic synthetic materials due to their better biocompatibility. Further, since biopolymers occur in nature, a ready supply of these raw materials is a plus.

U.S. Pat. No. 4,514,584 discloses an organic photovoltaic device wherein the photoactive electron donor component is a thermal condensation polymer and the photo-active electron acceptor component is a thermal condensation polymer, wherein these polymers contain photo-active flavin and pterin pigments.

There is a need for organic biopolymers to be utilized in electronic devices such as photovoltaic, optoelectronic and semiconductor devices—but, the prior art is limited in that it has identified only a relatively small range of materials that are generally suitable for these applications, and many of these materials lack the characteristics for particular types of applications.

### SUMMARY OF THE INVENTION

One object of the invention is to provide a biologically photoconductive organic dispersion with increased photovoltaic capability.

Another object of the invention is to provide a biologically photoconductive organic dispersion with increased electric conductivity.

A further object of the invention is to provide a biologically photoconductive organic dispersion with improved print capability.

These and other objects of the invention will become more apparent by reference to the Brief Description Of the Drawings and Detailed Description of the Preferred Embodiments of the Invention.

### BRIEF DESCRIPTION OF THE DRAWINGS

FIG. 1 is a schematic showing the use of various biologically photoconductive organic dispersions in various photovoltaic cells.

FIG. 2 is a graph showing short circuit current versus open circuit voltage for various photovoltaic cells (depicted in the ellipse) using various biologically photoconductive organic dispersions of the invention.

FIG. 3 is a graph showing power for various photovoltaic cells, and the photovoltaic cells using various biologically photoconductive organic dispersion of the invention (depicted in the ellipse).

### DETAIL DESCRIPTION OF PREFERRED EMBODIMENT OF THE INVENTION

The entire range of the electromagnetic spectrum or radiant energies or wave frequencies from the longest to the shortest wavelengths are as follows:

Gamma, x-rays, UV, visible, IR, microwave, and RF.

Solar cells are generally spectrum specific in that they are generally designed to work within the V, visible and IR range so as to match the absorption spectrum of the active element of the device to the solar spectrum range. The biologically photoconductive organic dispersion of the invention is:

1) a donor/acceptor blend in a single dispersion, wherein the donor domains is a synthetic polymer, and the acceptor domains is
a liquid organic semiconductor composite comprising, by weight about 14% single walled carbon nanotubes (SWNTs), about 57% of a biopolymer selected from lignin or melanin, and a dopant selected from the group consisting of iodine, phosphorous or boron, and this single layer (opt-glu) is disposed between the anode and metal cathode of the cell.

In the process of making opti-glue, sonication applies sound (ultrasound) energy through “a sonicator”—which is a bath of water through which sound is transmitted to help agitate particles within a vessel being sonicated. This speeds dissolution of the particles and is especially helpful when physically stirring is not possible. It also provides the energy for chemical reactions to proceed. The three sonication steps of the process help create the e-fields between materials with highly differentiated chemical potentials that are made close enough through dispersion.

The components of opti-glu suspension or dispersion contain about 14% carbon nanotubes, about 57% of a biopolymer of either lignin or melanin, and about 29% of iodine by weight as a dopant. Other components or property modifiers may be thickeners, or charged semiconductor particles—so long as these other components do not dilute the opti-glu to less than 90% by weight.

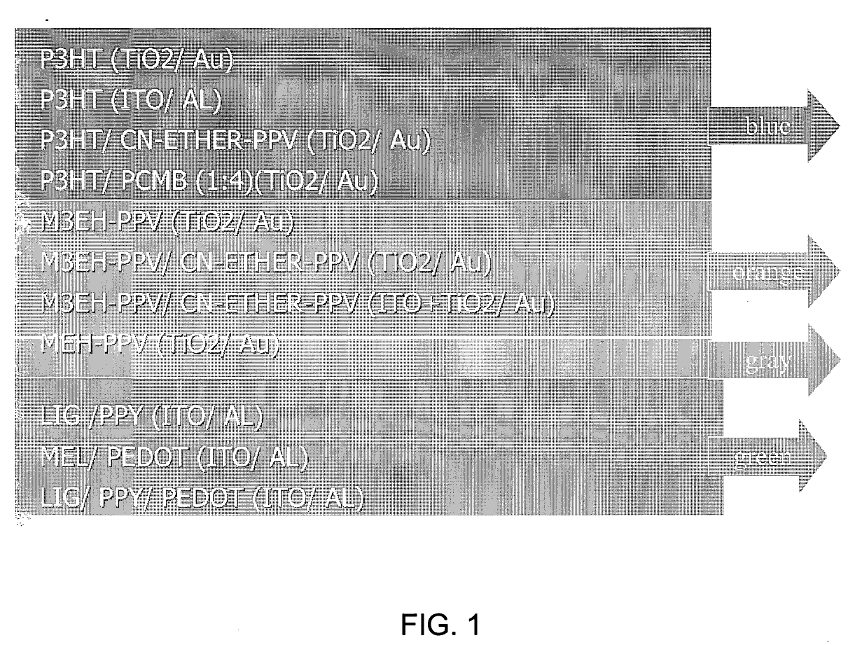

The clear ITO anode layer may be coated with glass or a flexible plastic, and the glass or flexible plastic may be coated with organic materials such as poly-(3-hexylthiophene)=P3HT or any of the polymers shown in the schematic of FIG. 1 to facilitate hole conduction and smooth the rough ITO layer to prevent shorts in the solar cell.

The compositions of these synthetic polymers on specific cell structures are:
poly-(3-hexylthiophene)=P3HT (TiO2/Au)
poly-(3-hexylthiophene)=P3HT (ITO/AL)
poly-(3-hexylthiophene)=P3HT/(poly[oxa-1,4-phenylene-1,2-(1-cyano)ethenylene-2,5-dioctyloxy-1,4-phenylene-1,2-(2-cyano)ethenylene-1,4-phenylene])=CN-ETHER-PPV (TiO2/Au)
poly-(3-hexylthiophene)=P3HT/methanofullerene 6,6-phenyl C₆₁-butyric acid methyl ester=PCMB (1:4)(TiO2/Au)
(poly[2,5-dimethoxy-1,4-phenylene-1,2-ethenylene-2-methoxy-5-(2-ethylhexyloxy)-(1,4-phenylene-1,2-ethenylene)])=M3EH-PPV (TiO2/Au)
(poly[2,5-dimethoxy-1,4-phenylene-1,2-ethenylene-2-methoxy-5-(2-ethylhexyloxy)-(1,4-phenylene-1,2-ethenylene)])=M3EH-PPV/(poly[oxa-1,4-phenylene-1,2-(1-cyano)ethenylene-2,5-dioctyloxy-1,4-phenylene-1,2-(2-cyano)ethenylene-1,4-phenylene])=CN-ETHER-PPV (TiO2/Au)
(poly[2,5-dimethoxy-1,4-phenylene-1,2-ethenylene-2-methoxy-5-(2-ethylhexyloxy)-(1,4-phenylene-1,2-ethenylene)]) M3EH-PPV/(poly[oxa-1,4-phenylene-1,2-(1-cyano)ethenylene-2,5-dioctyloxy-1,4-phenylene-1,2-(2-cyano)ethenylene-1,4-phenylene])=CN-ETHER-PPV (ITO+TiO2/Au)
poly(2-methoxy-5-(2′-ethyl-hexyloxy)-1,4-phenylene vinylene=MEH-PPV (TiO2/Au)
LIG/polypyrrole=PPY (ITO/AL)
MEL/Poly (3,4,-ethylenedioxythiopene) PEDOT (ITO/AL)
LIG/polypyrrole=PPY/Poly (3,4,-ethylenedioxythiopene)=PEDOT (ITO)/AL)

While not wishing to be bound by any theory in reference to the dynamics of the biologically optimized photovoltaic ITO/Al architecture of the invention, it is nevertheless believed that incident UV, visible and IR portions of the electromagnetic spectrum that give rise to green photons are absorbed by the biopolymer of lignin or melanin in use with the ITO/AL cell to produce a photocurrent. The ITO/AL architecture of the cell of the invention is less expensive than the sol-gel gold (TiO₂/Au) architecture—and in this connection, it should be noted from FIG. 1 that the architecture of the composition of organic photovoltaic devices using TiO₂/Au cells capture blue, orange and gray photons as opposed to the green photons shown by the invention cells employing lignin and melanin with ITO/Al.

The propensity for photovoltaic cells to become contaminated has usually necessitated that the manufacturing process by carried out in an environment of either clean air or under a nitrogren blanket, and this requires specialized equipment which increases the manufacturing costs. However, the photovoltaic cells of the present invention can be manufactured in the open air, and therefore eliminates the need for specialized equipment to prevent contamination.

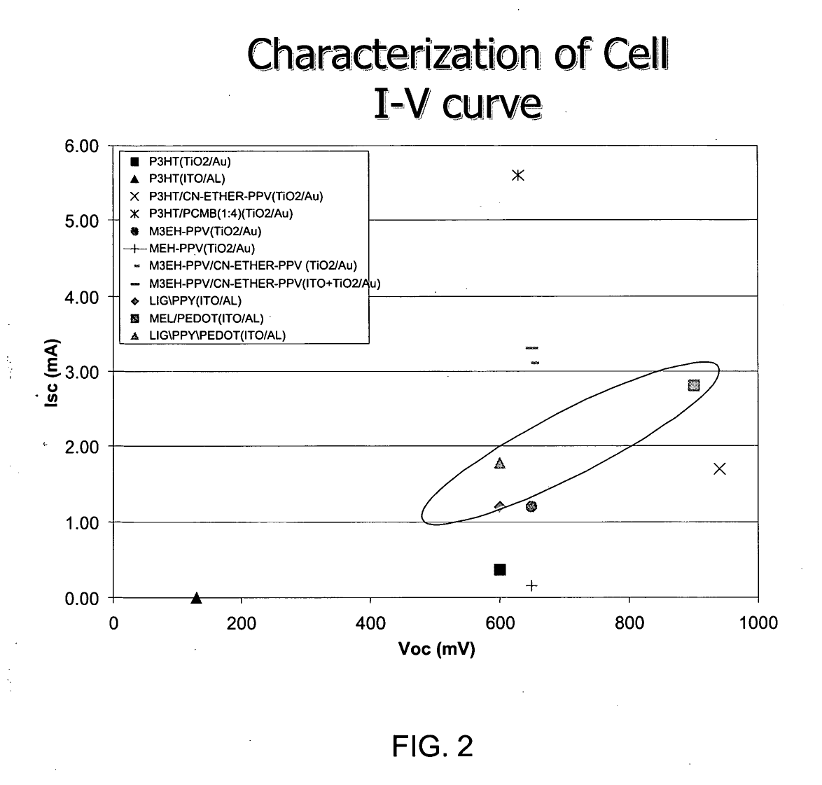

A characterization of cell I-V curves showing current density is shown in FIG. 2, wherein a graph shows short circuit current versus open circuit voltage for various types of biopolymers having a photoactive element used to sensitize the photoanode formed from an electrically conductive substrate. In FIG. 2, the ITO/Al photovoltaic cells of the invention using lignin or melanin is designated by the diamond, square or triangle shown in the elipse.

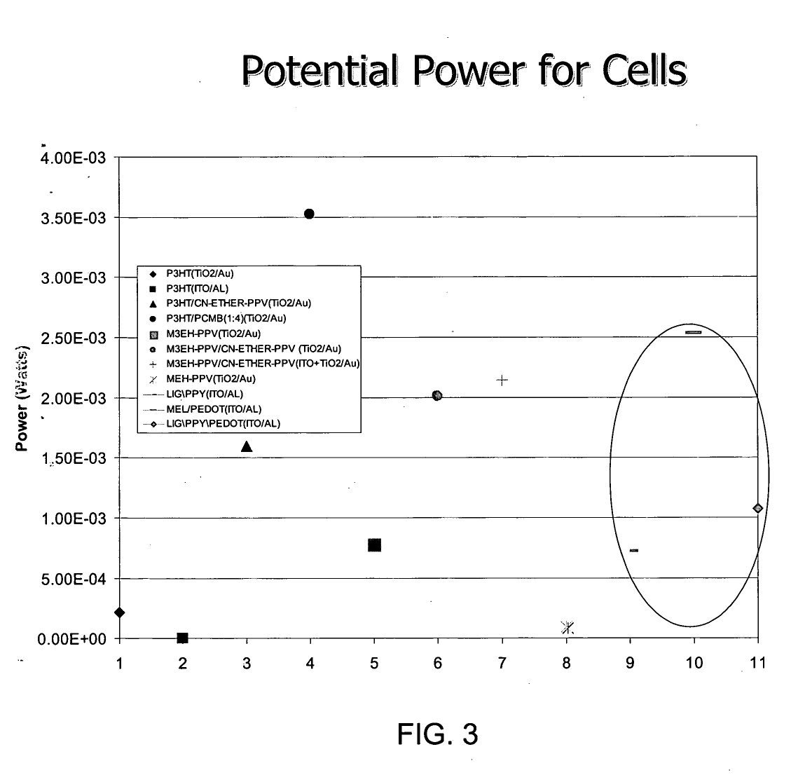

The power potential for the photovoltaic cells of the invention with the ITO/Al architecture in which the n-type semiconductor is coated with a broad band absorbing biopolymer such as lignin or melanin is represented by the symbols that are shown inside of the ellipse in FIG. 3.

It should be understood from the foregoing that variations of the invention are encompassed, and these variations and changes in form and detail can be made by those skilled in the art without departing from the scope of the invention, which is set forth in the appended claims, as follows:

We claim:

1. A biologically photoconductive dispersion comprising:
a donor/acceptor blend of a single layer, wherein the donor domains is a synthetic polymer, and the acceptor domains is
a liquid organic semiconductor composite comprising, by weight about 14% single walled carbon nanotubes (SWNTs), about 57% of a biopolymer selected from lignin or melanin, and a dopant selected from the group consisting of iodine, phosphorous or boron.

2. The biologically photoconductive dispersion of claim 1 wherein the dopant is iodine.

3. The biologically photoconductive dispersion of claim 1 wherein the dopant is phosphorous.

4. The biologically photoconductive dispersion of claim 1 wherein the dopant is boron.

5. The biologically photoconductive dispersion of claim 1 wherein said synthetic polymer is PPY.

6. The biologically photoconductive dispersion of claim 1 wherein said synthetic polymer is PEDOT.

7. The biologically photoconductive dispersion of claim 1 wherein said synthetic polymer is PPY/PEDOT.

8. The biologically photoconductive dispersion of claim 2 wherein said synthetic polymer is PPY.

9. The biologically photoconductive dispersion of claim 2 wherein said synthetic polymer is PEDOT.

10. The biologically photoconductive dispersion of claim 2 wherein said synthetic polymer is PPY/PEDOT.
